(19) United States
(12) Patent Application Publication
(10) Pub. No.: US 2023/0029967 A1
(43) Pub. Date: Feb. 2, 2023

(54) FIBER LASER DEVICE

(71) Applicant: FANUC CORPORATION, Yamanashi (JP)

(72) Inventors: Tetsuhisa TAKAZANE, Yamanashi (JP); Tetsuya CHIBA, Yamanashi (JP)

(73) Assignee: FANUC CORPORATION, Yamanashi (JP)

(21) Appl. No.: 17/791,185

(22) PCT Filed: Jan. 18, 2021
(86) PCT No.: PCT/JP2021/001484

§ 371 Date: Jul. 6, 2022

(30) Foreign Application Priority Data
Jan. 24, 2020 (JP) 2020-009744

(51) Int. Cl. H01S 3/094; H01S 3/067

(52) U.S. Cl. CPC H01S 3/094053; H01S 3/067; H01S 3/094011

(57) ABSTRACT

The present invention makes it possible to improve excitation efficiency in a fiber laser device provided with a TFB having an injection optical fiber not connected to an excitation light source. This fiber laser device is provided with: a plurality of excitation light sources, at least one fiber bundle that injects excitation light from the plurality of excitation light sources from a plurality of injection optical fibers and couples the excitation light to one optical fiber; and a cavity that introduces the excitation light coupled by the fiber bundle and amplifies and emits laser light. The number of the plurality of injection optical fibers of the fiber bundle is larger than the number of the plurality of excitation light sources, and a loop part is configured by connecting surplus injection optical fibers to which the excitation light is not injected among the plurality of injection optical fibers of the fiber bundle.

### TECHNICAL FIELD

The present invention relates to a fiber laser device.

### BACKGROUND ART

Excitation light sources that emit laser light are used for excitation in fiber laser devices. Generally, a plurality of excitation light sources are provided, according to an output of laser light (see, for example, Patent Document 1).

In a fiber laser device provided with a plurality of excitation light sources, introducing light from the plurality of excitation light sources into a cavity by a tapered fiber bundle (hereinafter referred to simply as a TFB) is also known. A TFB has a structure wherein a plurality of injection optical fibers are coupled into one coupling optical fiber. The plurality of excitation light sources are individually connected to the plurality of injection optical fibers. Accordingly, the TFB couples the excitation light emitted by the excitation light sources into the one coupling optical fiber and introduces the excitation light into the cavity.

There is a specific number of injection optical fibers for the TFB that is easy to produce. As such, there may be cases in which the number of excitation light sources required for excitation and the number of injection optical fibers of the TFB do not match, and some injection optical fibers of the TFB are not connected to excitation light sources. Injection optical fibers not connected to excitation light sources will receive feedback light from the cavity, and therefore, the end faces of the injection optical fibers are treated in order to safely absorb the feedback light without reflecting it.
Patent Document 1: Japanese Unexamined Patent Application, Publication No. H07-115240

### DISCLOSURE OF THE INVENTION

### Problems to be Solved by the Invention

Feedback light includes excitation light that was not used for excitation. When there are injection optical fibers that are not connected to excitation light sources present, there is a problem in that excitation light transmitted from the excitation light sources to the cavity goes to waste, reducing excitation efficiency. Therefore, there is a demand for improving excitation efficiency in a fiber laser device provided with a TFB having injection optical fibers that are not connected to excitation light sources.

### Means for Solving the Problems

An aspect of the present disclosure is a fiber laser device including: a plurality of excitation light sources; at least one fiber bundle that injects excitation light from the plurality of excitation light sources from a plurality of injection optical fibers and couples the excitation light into one coupling optical fiber; and a cavity that introduces the excitation light coupled by the fiber bundle and amplifies and emits laser light, wherein the number of the plurality of injection optical fibers is larger than the number of the plurality of excitation light sources, and a loop part is constituted by connecting surplus injection optical fibers to which the excitation light is not injected among the plurality of injection optical fibers of the fiber bundle.

### Effects of the Invention

According to an aspect of the present invention, excitation efficiency in a fiber laser device provided with a TFB having injection optical fibers that are not connected to excitation light sources can be improved.

### BRIEF DESCRIPTION OF THE DRAWINGS

FIG. 1 is a schematic view of a fiber laser device according to an embodiment of the present disclosure;

FIG. 2 is a schematic view of a cross-section taken along line ii-ii in FIG. 1;

FIG. 3 is a schematic view of a cross-section taken along line iii-iii in FIG. 1;

FIG. 4 is a schematic view of a fiber laser device according to another embodiment of the present disclosure;

FIG. 5 is a schematic view of a fiber laser device according to another embodiment of the present disclosure;

FIG. 6 is a schematic view of a fiber laser device according to another embodiment of the present disclosure; and

FIG. 7 is a schematic view of a fiber laser device according to another embodiment of the present disclosure.

### PREFERRED MODE FOR CARRYING OUT THE INVENTION

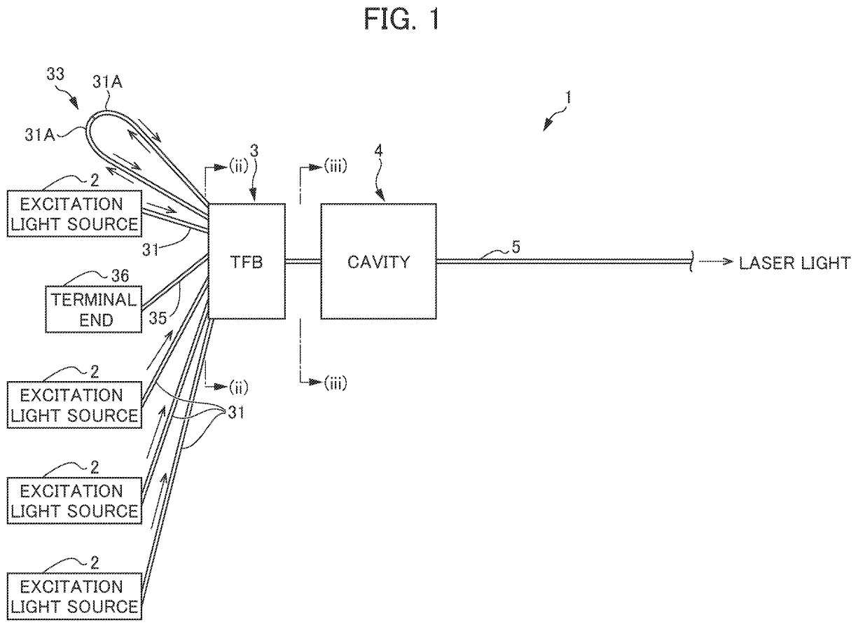

Below, a fiber laser device according to an aspect of the present disclosure is described with reference to the drawings. As illustrated in FIG. 1, a fiber laser device 1 includes a plurality of excitation light sources 2, a TFB 3, a cavity 4, and a laser light emission optical fiber 5. In the cavity 4, the opposite side from the laser light emission optical fiber 5 (the left side in FIG. 1) is referred to as the front (upstream side, input side), and the same side as the laser light emission optical fiber 5 (the right side in FIG. 1) is referred to as the rear (downstream side, output side). In the fiber laser device 1, the TFB 3 connected to a plurality of excitation light sources 2 is provided only in front of the cavity 4.

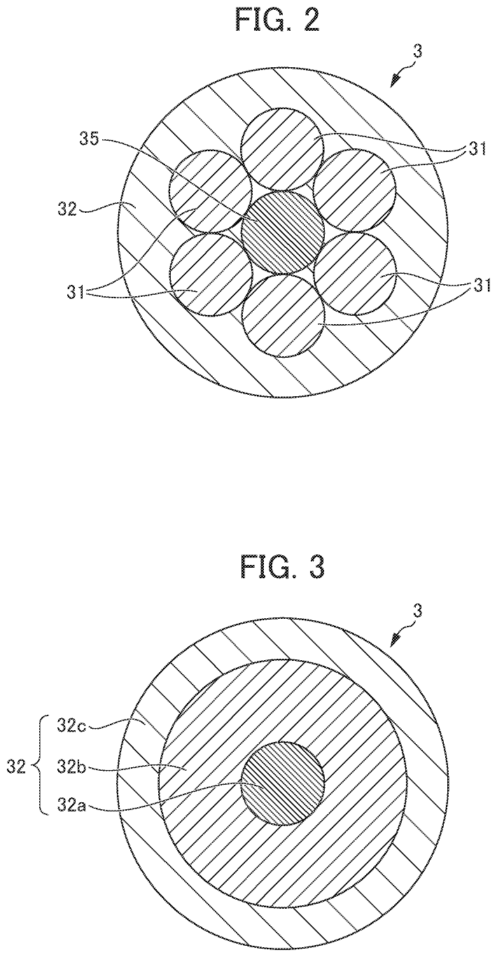

The TFB 3 according to the present embodiment is a 6+1 type fiber bundle. As illustrated in FIG. 2, on one end side of the TFB 3, there are provided six injection optical fibers 31 and one signal optical fiber 35. As illustrated in FIG. 3, on the other end side of the TFB 3, there is provided one coupling optical fiber 32.

The injection optical fibers 31 and the signal optical fiber 35 are each formed having a smaller diameter than that of the coupling optical fiber 32. The six injection optical fibers 31 are bundled together by being closely arranged around the one signal optical fiber 35 in the center. By having end faces of the injection optical fibers 31 and the signal optical fiber 35 be bonded to an end face of the coupling optical fiber 32, the TFB 3 is configured such that excitation light injected from the injection optical fibers 31 is coupled into the one coupling optical fiber 32.

The coupling optical fiber 32 has a diameter compatible with the structure in which the six injection optical fibers 31 and the one signal optical fiber 35, for a total of seven fibers, are bundled together. The coupling optical fiber 32 has a core 32a arranged at the center, a first cladding 32b arranged surrounding the core 32a, and a second cladding 32c arranged surrounding the first cladding 32b. Excitation light injected from the injection optical fibers 31 is injected into the first cladding 32b. The second cladding 32c constitutes an outermost layer that reflects all excitation light in the first cladding 32b to confine the excitation light within the coupling optical fiber 32.

The cavity 4 has an amplification fiber (not shown) connected to the coupling optical fiber 32 of the TFB 3. The amplification optical fiber of the cavity 4 has the same structure as the coupling optical fiber 32 of the TFB 3, and introduces excitation light from the first cladding 32b of the coupling optical fiber 32 into a first cladding of the amplification optical fiber. The cavity 4 excites a rare earth element such as Ytterbium (Yb) added to a core of the amplification optical fiber with the excitation light introduced from the coupling optical fiber 32 of the TFB 3 to amplify and generate laser light. The generated laser light is emitted from the fiber laser device 1 by the laser light emission optical fiber 5 connected to the amplification optical fiber of the cavity 4.

The plurality of excitation light sources 2 are respectively connected to the injection optical fibers 31 of the TFB 3. As illustrated in FIG. 1, the fiber laser device 1 has four excitation light sources 2. The four excitation light sources 2 are respectively connected to four injection optical fibers 31 of the six injection optical fibers 31 provided to the TFB 3. Therefore, the TFB 3 has two surplus injection optical fibers 31A, 31A into which excitation light is not injected. The signal optical fiber 35 is end face treated by a terminal end 36.

The end faces of the two surplus injection optical fibers 31A, 31A in the fiber laser device 1 are optically connected to each other, thereby constituting a loop part 33. Being optically connected as used here means being connected such that light can pass between the surplus injection optical fibers 31A, 31A. Therefore, of the excitation light introduced into the cavity 4 via the TFB 3, excitation light that is not used for excitation and returns to the TFB 3 (feedback light) is reintroduced into the cavity 4 by the loop part 33 and is reused for excitation in the cavity 4. Thus, according to this fiber laser device 1, excitation efficiency in the cavity 4 can be improved.

The TFB 3 illustrated in FIG. 1 forms one loop part 33 by two surplus injection optical fibers 31A, 31A. However, when four or more surplus injection optical fibers 31 are present in the TFB 3, two or more loop parts 33 may be provided to the TFB 3.

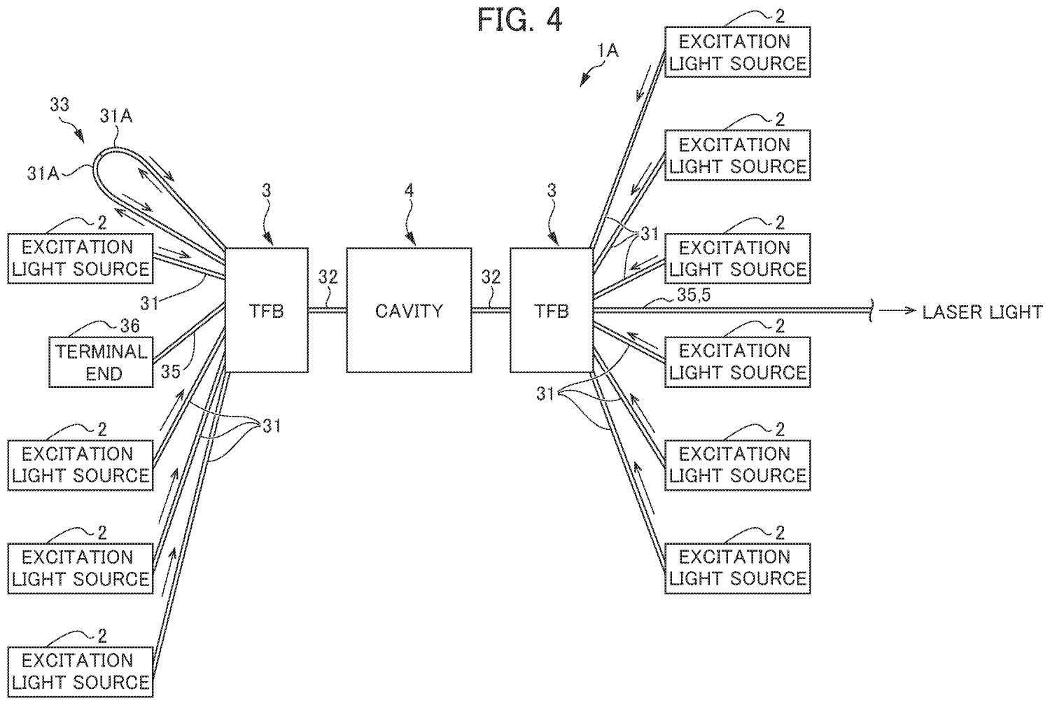

FIG. 4 illustrates a fiber laser device 1A according to another embodiment of the present disclosure. In the fiber laser device 1A, components with the same reference numerals as in the fiber laser device 1 illustrated in FIG. 1 illustrate components of the same configuration, and therefore, the above detailed description thereof is omitted below. The fiber laser device 1A has a TFB 3 both in front of and to the rear of the cavity 4.

In this fiber laser device 1A, the loop part 33 is constituted by the surplus injection optical fibers 31A, 31A only of the TFB 3 arranged in front of the cavity 4 being optically connected to each other. In the TFB 3 arranged to the rear of the cavity 4, the one signal optical fiber 35 in the center is connected to the laser light emission optical fiber 5 emitting laser light generated in the cavity 4, and the surrounding six injection optical fibers 31 are respectively connected to excitation light sources 2.

In this way, even when a TFB 3 is arranged both in front and to the rear of the cavity 4, excitation efficiency in the cavity 4 can be improved by providing a loop part 33 to one TFB 3 of the TFBs. In this fiber laser device 1A, the loop part 33 is provided only to the front TFB 3, which avoids infinite circulation of feedback light from the cavity 4 between the front and rear TFBs 3, 3. As such, there is no risk of laser light of an unexpected wavelength being amplified.

The TFB 3 having the loop part 33 may be either TFB 3 of the TFBs in front of and to the rear of the cavity 4. Thus, in the fiber laser device 1A, the TFB 3 having the loop part 33 may be arranged to the rear of the cavity 4.

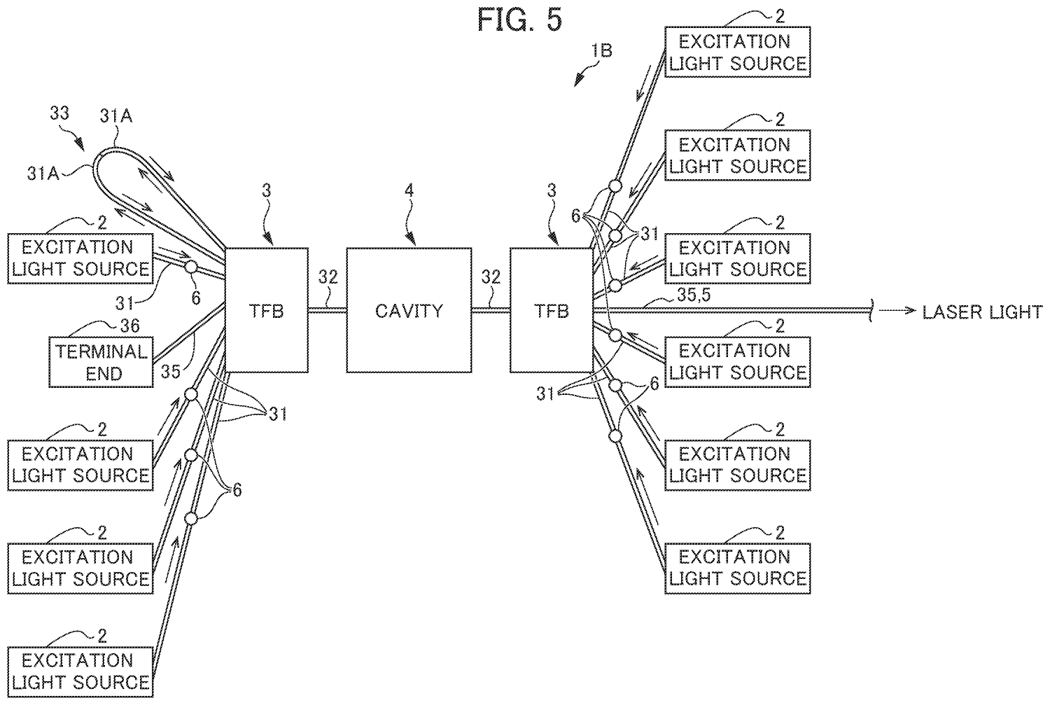

FIG. 5 illustrates a fiber laser device 1B according to another embodiment of the present disclosure. In the fiber laser device 1B, components with the same reference numerals as in the fiber laser device 1 illustrated in FIG. 1 and as in the fiber laser device 1A illustrated in FIG. 4 illustrate components of the same configuration, and therefore, the above detailed description thereof is omitted below. Like the fiber laser device 1A, the fiber laser device 1B has a TFB 3 both in front of and to the rear of the cavity 4, and only the front TFB 3 is provided with a loop part 33.

In the two TFBs 3, 3 of the fiber laser device 1B, each of the injection optical fibers 31 connected to an excitation light source 2 is provided with an isolator 6. The isolator 6 has a function of transmitting excitation light from the excitation light source 2 toward the cavity 4 via the TFB 3, and blocking feedback light returning from the cavity 4 toward the excitation light source 2 via the TFB 3.

Thus, even when there is a possibility of strong feedback light returning from the cavity 4 to the excitation light source 2, the strong feedback light can be blocked by the isolator 6. Therefore, according to this fiber laser device 1B, in addition to the effect of improving excitation efficiency in the cavity 4, an effect of protecting the excitation light sources 2 from strong feedback light is also achieved.

The isolator 6 may also be provided to the injection optical fibers 31 connected to the excitation light sources 2 in the laser light device 1 illustrated in FIG. 1.

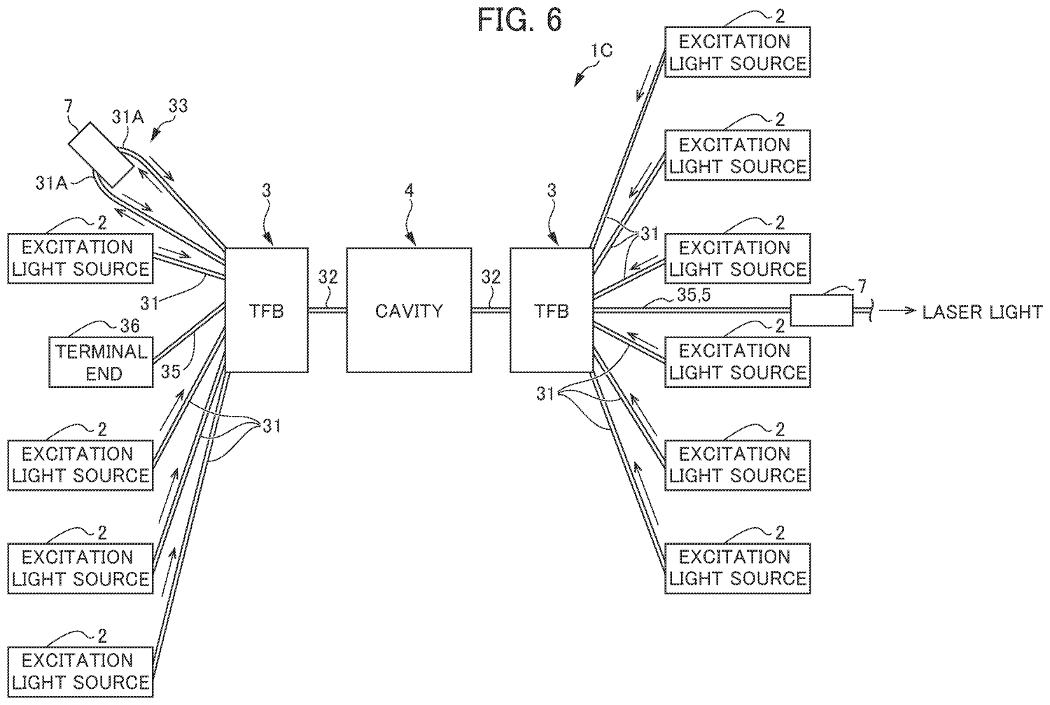

FIG. 6 illustrates a fiber laser device 1C according to another embodiment of the present disclosure. In the fiber laser device 1C, components with the same reference numerals as in the fiber laser device 1 illustrated in FIG. 1 and as in the fiber laser device 1A illustrated in FIG. 4 illustrate components of the same configuration, and therefore, the above detailed description thereof is omitted below. Like the fiber laser device 1A illustrated in FIG. 4, the fiber laser device 1C has a TFB 3 both in front of and to the rear of the cavity 4.

In this fiber laser device 1C, a filter 7 is provided respectively to the loop part 33 provided to the TFB 3 arranged in front of the cavity 4, and to the laser light emission optical fiber 5. The filter 7 has a function of blocking light other than excitation light.

Therefore, according to this fiber laser device 1C, in addition to the effect of improving excitation efficiency in the cavity 4, an effect of blocking light other than excitation light by the filter 7 provided to the injection optical fibers 3A, 3A is also achieved. This achieves an effect of preventing light other than excitation light from circulating between the TFB 3 and the cavity 4 and being unintentionally amplified. Further, the filter 7 provided to the laser light emission optical fiber 5 is able to block light from the exterior of the fiber laser device 1C from entering the cavity 4 through the laser emission optical fiber 5.

In the fiber laser device 1C, the filter 7 may also be provided only to either one of the loop part 33 and the laser emission optical fiber 5. The filter 7 may also be provided to either one of the loop part 33 and the laser emission optical fiber 5 in the fiber laser device 1 illustrated in FIG. 1. The fiber laser devices 1, 1A, 1B, and 1C may be provided with both the isolator 6 and the filter 7.

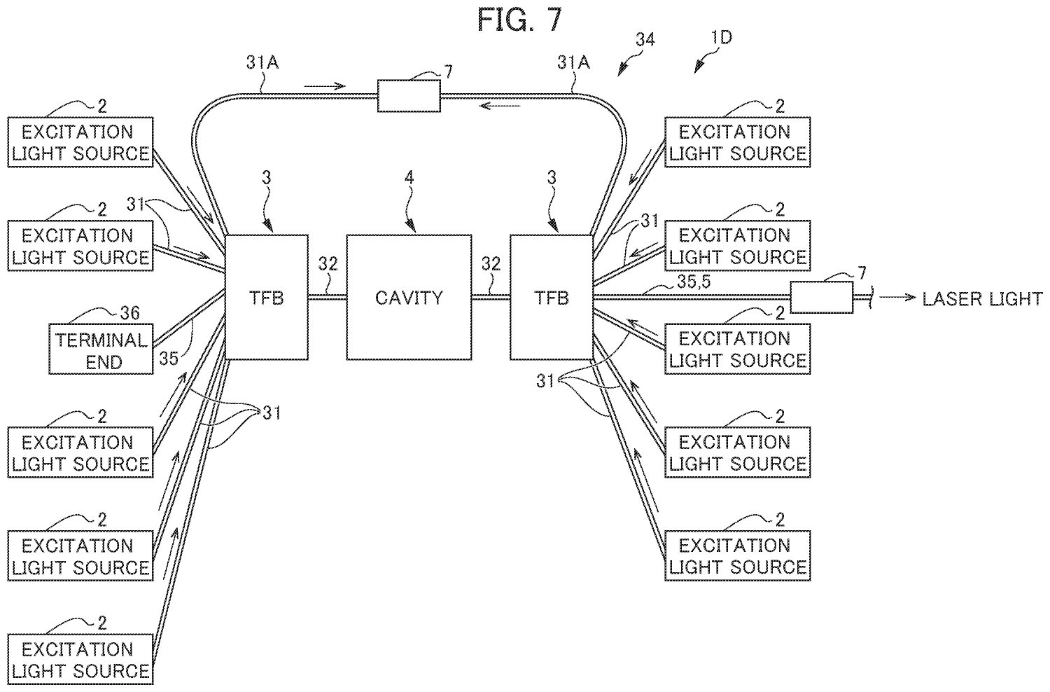

FIG. 7 illustrates a fiber laser device 1D according to another embodiment of the present disclosure. In the fiber laser device 1D, components with the same reference numerals as in the fiber laser device 1 illustrated in FIG. 1 and as in the fiber laser device 1A illustrated in FIG. 4 illustrate components of the same configuration, and therefore, the above detailed description thereof is omitted below. Like the fiber laser device 1A illustrated in FIG. 4, the fiber laser device 1D has a TFB 3 both in front of and to the rear of the cavity 4.

In the fiber laser device 1D, five injection optical fibers 31 of the injection optical fibers 31 of the TFB 3 arranged in front of the cavity 4 are respectively connected to excitation light sources 2. In addition, five injection optical fibers 31 of the injection optical fibers 31 of the TFB 3 arranged to the rear of the cavity 4 are respectively connected to excitation light sources 2. The one surplus injection optical fiber 31A of the TFB 3 arranged in front of the cavity 4 and the one surplus injection optical fiber 31A of the TFB 3 arranged to the rear of the cavity 4 are optically connected to each other, whereby one loop part 34 is formed across the two TFBs 3, 3.

Accordingly, feedback light heading toward each excitation light source 2 from the cavity 4 via the TFBs 3, 3 is returned to the cavity 4 by the loop part 34. Thus, according to this fiber laser device 1D, excitation efficiency in the cavity 4 can be improved. A configuration with this kind of loop part 34 is effective when an equal number of excitation light sources 2 are arranged respectively in front of and to the rear of the cavity 4.

In the fiber laser device 1D, the loop part 34 may be provided with a filter 7 for blocking light other than excitation light. This can prevent light other than excitation light from being unintentionally amplified in the cavity 4. The filter 7 may also be provided to the laser emission optical fiber 5. In addition, although not shown here, each of the injection optical fibers 31 connected to the excitation light sources 2 in the fiber laser device 1D may be provided with an isolator 6.

In the embodiments described above, the fiber bundles are not limited to 6+1 type bundles. The fiber bundles may have even more injection optical fibers 31, such as 18+1, etc.

### EXPLANATION OF REFERENCE NUMERALS

1, 1A, 1B, 1C, 1D Fiber laser device
2 Excitation light source
3 Tapered fiber bundle
31 Injection optical fiber
31A Surplus injection optical fiber
32 Coupling optical fiber
33, 34 Loop part
35 Signal optical fiber
4 Cavity
6 Isolator
7 Filter

1. A fiber laser device comprising: a plurality of excitation light sources;
at least one fiber bundle that injects excitation light from the plurality of excitation light sources from a plurality of injection optical fibers and couples the excitation light into one coupling optical fiber; and
a cavity that introduces the excitation light coupled by the fiber bundle and amplifies and emits laser light,
wherein the number of the plurality of injection optical fibers of the fiber bundle is larger than the number of the plurality of excitation light sources, and
a loop part is constituted by connecting surplus injection optical fibers to which the excitation light is not injected among the plurality of injection optical fibers of the fiber bundle.

2. The fiber laser device according to claim 1, wherein the fiber bundle comprises a fiber bundle provided in front of the cavity and a fiber bundle provided to the rear of the cavity, and
one of the fiber bundle in front of the cavity and the fiber bundle to the rear of the cavity is provided with the loop part.

3. The fiber laser device according to claim 1, wherein the fiber bundle comprises a fiber bundle provided in front of the cavity and a fiber bundle provided to the rear of the cavity, and
the loop part is constituted by connecting a surplus injection optical fiber of the fiber bundle in front of the cavity to a surplus injection optical fiber of the fiber bundle to the rear of the cavity.

4. The fiber laser device according to claim 1, wherein each of the injection optical fibers connected to the plurality of excitation light sources is provided with an isolator that transmits the excitation light from the excitation light source toward the cavity and blocks the excitation light returning from the cavity toward the excitation light source.

5. The fiber laser device according to claim 1, wherein the loop part is provided with a filter that blocks light other than the excitation light.

6. The fiber laser device according to claim 1, further comprising a laser light emission fiber that emits laser light from the cavity and is provided with a filter that blocks light other than the excitation light.
